(19) United States
(12) Patent Application Publication
(10) Pub. No.: US 2010/0304556 A1
(43) Pub. Date: Dec. 2, 2010

(54) INTEGRATED CIRCUIT SYSTEM WITH VERTICAL CONTROL GATE AND METHOD OF MANUFACTURE THEREOF

(75) Inventors: Chunshan Yin, Singapore (SG); Jae Gon Lee, Singapore (SG); Shyue Seng Tan, Singapore (SG); Elgin Kiok Boone Quek, Singapore (SG); Chung Foong Tan, Singapore (SG); Lee Wee Teo, Singapore (SG)

Correspondence Address: LAW OFFICES OF MIKIO ISHIMARU, 333 W. EL CAMINO REAL, SUITE 330, SUNNYVALE, CA, 94087, US

(73) Assignee: CHARTERED SEMICONDUCTOR MANUFACTURING LTD., Singapore (SG)

(21) Appl. No.: 12/471,803

(22) Filed: May 26, 2009

(51) Int. Cl. H01L 21/28

(52) U.S. Cl. 438/593; 257/E21.21

(57) ABSTRACT

A method of manufacture of an integrated circuit system includes: providing a mesa over a substrate; forming a trench in the substrate adjacent the mesa; forming a second gate and a charge storage material along a trench sidewall; and forming a first gate from the mesa.

### TECHNICAL FIELD

The present invention relates generally to an integrated circuit system, and more particularly to an integrated circuit system with a vertical control gate.

### BACKGROUND ART

Integrated circuits find application in many of today's consumer electronics, such as cell phones, video cameras, portable music players, printers, computers, calculators, automobiles, etc. Integrated circuits may include a combination of active devices, passive devices and their interconnections.

In some instances, integrated circuits may take the form of nonvolatile memory, which can be an integrated circuit designed to store digital data in the form of an electrical charge. Uniquely, a nonvolatile memory charge remains in storage even after the power is turned off. Accordingly, the use of nonvolatile memory devices can be particularly advantageous for power saving applications or in applications where power can be interrupted.

Nonvolatile memory usually takes one of two forms, a floating gate form or a split-gate form. Nonvolatile memory cells utilizing the split-gate type structure typically employ a planar configuration wherein a control gate overlaps at least a portion of a select gate. Unfortunately, in these conventional programming schemes, the programming current flows in a path parallel to the control gate, where a relatively small number of the programming electrons are injected into the control gate, thereby slowing program speed times.

Furthermore, as the current processing technology node continues to decrease, area has become one of the most critical elements of memory cell production. Unfortunately, both the control gate and select gate of a split-gate nonvolatile memory device consume precious wafer area, thereby adversely impacting the memory cells capacity per fixed die area (e.g., the amount of information that can be stored in a defined area).

Thus, a need still remains for a reliable integrated circuit system and method of fabrication, wherein the integrated circuit system exhibits improved programming speed, while increasing the amount of information that can be stored in a defined area. In view of the ever-increasing commercial competitive pressures, increasing consumer expectations, and diminishing opportunities for meaningful product differentiation in the marketplace, it is increasingly critical that answers be found to these problems. Moreover, the ever-increasing need to save costs, improve efficiencies, and meet such competitive pressures adds even greater urgency to the critical necessity that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit system including: providing a mesa over a substrate; forming a trench in the substrate adjacent the mesa; forming a second gate and a charge storage material along a trench sidewall; and forming a first gate from the mesa.

Certain embodiments of the invention have other steps or elements in addition to or in place of those mentioned above. The steps or element will become apparent to those skilled in the art from a reading of the following detailed description when taken with reference to the accompanying drawings.

### BRIEF DESCRIPTION OF THE DRAWINGS

FIG. 1 is a partial cross sectional view of an integrated circuit system in an initial stage of manufacture in accordance with an embodiment of the present invention.

FIG. 2 is the structure of FIG. 1 after forming a trench.

FIG. 3 is the structure of FIG. 2 after further processing.

FIG. 4 is the structure of FIG. 3 after depositing a control gate layer.

FIG. 5 is the structure of FIG. 4 after further processing.

FIG. 6 is the structure of FIG. 5 after forming a first gate.

FIG. 7 is the structure of FIG. 6 after further processing.

FIG. 8 is a flow chart of a method of manufacture of an integrated circuit system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals.

For expository purposes, the term “horizontal” as used herein is defined as a plane parallel to the conventional plane or surface of the substrate, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures.

The term “processing” as used herein includes deposition of material or photoresist, patterning, exposure, development, etching, cleaning, and/or removal of the material or photoresist as required in forming a described structure.

The term “on” is defined to mean there is direct contact among elements.

The terms “example” or “exemplary” are used herein to mean serving as an instance or illustration. Any aspect or embodiment described herein as an “example” or as “exemplary” is not necessarily to be construed as preferred or advantageous over other aspects or designs.

The terms “first” and “second” as used herein are for purposes of differentiation between elements only and are not to be construed as limiting the scope of the present invention.

The term “layer” encompasses both the singular and the plural unless otherwise indicated.

The term “self aligned” is used herein to mean the act of performing one or more steps involving one or more materials such that the features formed are automatically aligned with respect to one another in that processing step.

The term “programming speed” is used herein to mean the duration of time needed to change the control gate threshold voltage a desired amount, e.g., 1 volt.

Generally, the following embodiments relate to the formation of an integrated circuit system including, but not limited to, a split-gate nonvolatile memory device that utilizes a vertical control gate to reduce memory cell area while providing improved programming speed by orienting the current flow perpendicular to the plane of the control gate. It will be appreciated by those skilled in the art that the present embodiments disclosed herein can help to improve the charge trapping efficiency of the integrated circuit system.

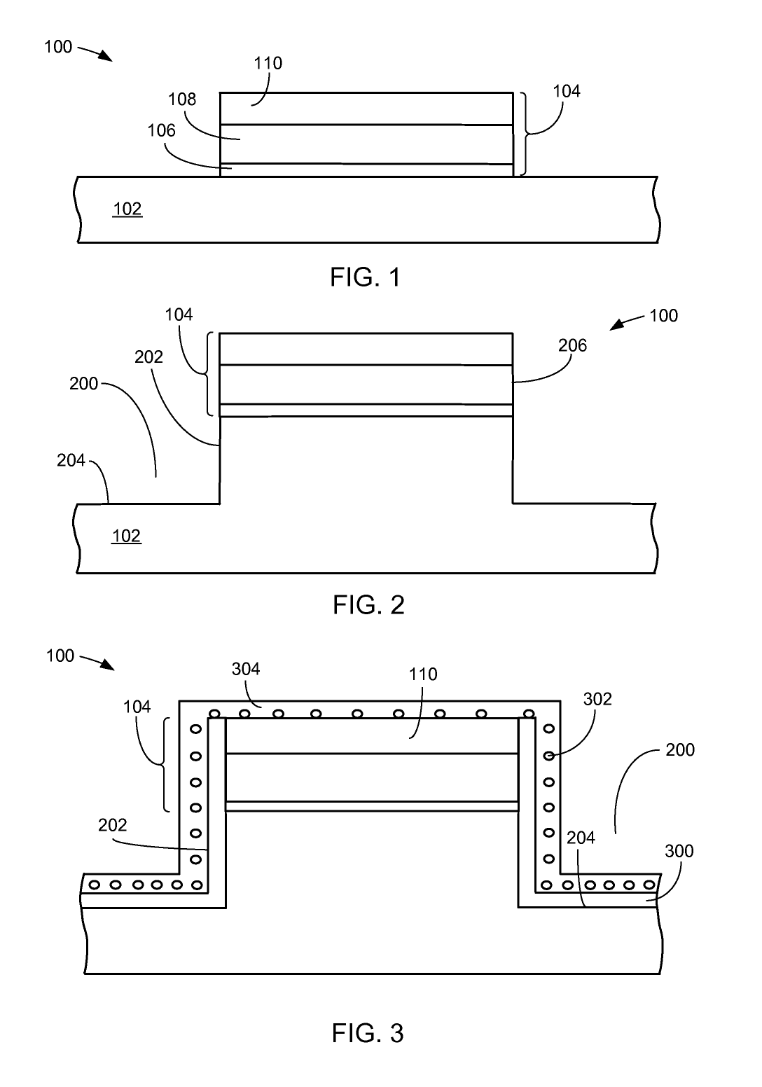

FIGS. 1-8, which follow, depict by way of example and not by limitation, an exemplary process flow for the formation of an integrated circuit system and they are not to be construed as limiting. It is to be understood that a plurality of conventional processes that are well known within the art and not repeated herein, may precede or follow FIGS. 1-8. Moreover, it is to be understood that many modifications, additions, and/or omissions may be made to the below described process without departing from the scope of the claimed subject matter. For example, the below described process may include more, fewer, or other steps. Additionally, steps may be performed in any suitable order without departing from the scope of the present invention.

Furthermore, it is to be understood that one or more of the integrated circuit system could be prepared at one time on a medium, which could be separated into individual or multiple integrated circuit assemblies at a later stage of fabrication.

It should be understood that the definitions and nomenclature used herein are given by way of example only and that one skilled in the art would readily understand that other definitions and nomenclature may be used to illustrate the techniques, systems, devices, and methods described herein.

Moreover, the thickness of the layers described herein will depend upon the design rules and the current process technology node. However, it will be understood by those skilled in the art that the present embodiments are not limited to any specific process technology node, nor to any specific value in any of the process parameters described herein.

Referring now to FIG. 1, therein is shown a partial cross sectional view of an integrated circuit system 100 in an initial stage of manufacture in accordance with an embodiment of the present invention. By way of example, the integrated circuit system 100 can be used within processor components, memory components, logic components, digital components, analog components, mixed-signal components, power components, radio-frequency (RF) components (e.g., RF CMOS circuits), digital signal processor components, micro-electromechanical components, optical sensor components, and so forth, in numerous configurations and arrangements as may be needed. In at least one embodiment, the integrated circuit system 100 may include a non-volatile memory (“NVM”) array utilizing a split-gate structure.

Generally, the integrated circuit system 100 includes a substrate 102 formed from any semiconducting material, such as, Si, SiC, SiGe, Si/SiGe, SiGeC, Ge, GaAs, InAs, InP, other III/V or II/VI compound semiconductors, as well as silicon-on-insulator configurations. Additionally, the substrate 102 may also include doped and undoped configurations, epitaxial layers, strained configurations, and one or more crystal orientations (e.g.—<100>, <110>, and/or <111> orientations), which may be strategically employed to optimize carrier mobility within an active device.

In some embodiments, the substrate 102 may possess a thickness ranging from about one hundred (100) nanometers to about several hundred microns, for example.

However, the examples provided for the substrate 102 are not to be construed as limiting and the composition of the substrate 102 may include any surface, material, configuration, or thickness that physically and electrically enables the formation of active and/or passive device structures.

In at least one embodiment, a mesa 104 can be formed over or on the substrate 102. Generally, the mesa 104 may include a select gate dielectric layer 106, a select gate layer 108, and a cap layer 110. In some embodiments, the mesa 104 can formed over or on selected portions of the substrate 102, and in other embodiments, the select gate dielectric layer 106, the select gate layer 108, and the cap layer 110 can be formed over or on the entirety of the substrate 102 and patterned to form the mesa 104. Regardless of how the mesa 104 is formed, portions of the substrate 102 adjacent the mesa 104 are left exposed for further processing.

In yet another embodiment, the mesa 104 need not be formed and the select gate dielectric layer 106, the select gate layer 108, and the cap layer 110 can be formed over or on the entirety of the substrate 102. In accordance with this embodiment, the select gate dielectric layer 106, the select gate layer 108, and the cap layer 110 can be patterned/etched during a subsequent trench formation step.

The select gate dielectric layer 106, also referred to as a first gate dielectric layer, can be formed over or on the substrate 102. The select gate dielectric layer 106 can be made from materials including, but not limited to, silicon oxide, silicon oxynitride, silicon nitride, a silicon oxide/nitride/oxide stack, a high-k dielectric material (i.e., one having a dielectric constant value greater than silicon oxide), or a combination thereof. However, it is to be understood that the type of material chosen for the select gate dielectric layer 106 is not limited to the preceding examples; for example, the select gate dielectric layer 106 may include any material that permits induction of a charge in a channel region when an appropriate voltage is applied to a gate. In accordance with the scope of the present embodiments, other materials, which may be known to those skilled in the art for gate structures, may also be used for the select gate dielectric layer 106.

The select gate dielectric layer 106 can be formed by thermal oxidation, atomic layer deposition (ALD), chemical vapor deposition (CVD), or physical vapor deposition (PVD). The select gate dielectric layer 106 may also include a multilayer structure and/or different materials for n-channel field effect transistor (NFET) and p-channel field effect transistor (PFET) devices. In at least one embodiment, the select gate dielectric layer 106 may include a multi-layer structure, such as a first layer of an oxide and a second layer of a high-k material.

Formed over or on the select gate dielectric layer 106 can be a first gate layer, such as the select gate layer 108. The select gate layer 108 can be made from conventional materials including doped and undoped semiconducting materials (such as, for example, polySi, amorphous Si, or SiGe), a metal, a metallic alloy, a silicide, a metal nitride, a metal oxide, a carbon nanotube, or a combination thereof. By way of example, if the select gate layer 108 includes a metal, the metal may include copper, tungsten, aluminum, aluminum alloy, palladium, titanium, tantalum, nickel, cobalt, and molybdenum. Furthermore, by way of example, if the select gate layer 108 includes a metal silicide, the metal silicide may include copper silicide, tungsten silicide, aluminum silicide, palladium silicide, titanium silicide, tantalum silicide, nickel silicide, cobalt silicide, erbium silicide, and molybdenum silicide. In accordance with the scope of the present embodiments, other materials, which may be known to those skilled in the art for gate structures, may also be used for the select gate layer 108.

Generally, the select gate layer 108 can be formed by CVD, PVD, silicidation, plating, and/or ALD. The select gate layer 108 may also include a multilayer structure and/or a dual structure including different gate heights for different gate structures.

It will be appreciated by those skilled in the art that the thickness of the select gate dielectric layer 106 and the select gate layer 108 can vary with the design specifications and/or the current technology process node (e.g., 45 nm, 32 nm, etc.) for the integrated circuit system 100.

Subsequent to forming the select gate layer 108, the cap layer 110 can be formed over or on the select gate layer 108. In at least one embodiment, the cap layer 110 may include a nitrogen containing material, such as silicon nitride. However, it is to be understood that the composition of the cap layer 110 is not limited to the preceding example and may include any material that helps to protect the select gate layer 108 and the select gate dielectric layer 106 during subsequent processing.

Referring now to FIG. 2, therein is shown the structure of FIG. 1 after forming a trench 200. Generally, the trench 200 may include a trench sidewall 202 and a trench bottom 204, wherein the trench sidewall 202 is aligned with a mesa sidewall 206. In at least one embodiment, the etching process used to form the trench 200 can be described as a self-aligned process because the mesa 104 can act as the mask for forming the trench 200.

In general, the trench 200 can be formed by using an etching process that is selective to the material of the substrate 102. In at least one embodiment, the substrate 102 can be etched using an anisotropic process, such as reactive ion etching (RIE), to form the trench 200 adjacent the mesa 104. It will be appreciated by those skilled in the art that such an anisotropic etching process will help to form the trench sidewall 202 in a vertical orientation that is substantially parallel and co-planar with the mesa sidewall 206.

However, it is to be understood that the etching process employed to form the trench 200 may include any etching process (e.g., wet or dry) that permits selective removal of the substrate 102 while minimizing any detrimental etching effects upon the mesa 104.

Generally, the depth of the trench 200 can be adjusted to affect the desired gate length of a subsequently formed control gate within the trench 200, e.g., as the depth of the trench 200 increases so does the gate length of the control gate. In at least one embodiment, the depth of the trench 200 can vary with the current manufacturing process technology node. However, it is to be understood that the depth of the trench 200 is only to be limited by the desired write, erase, and programming speed characteristics of the integrated circuit system 100.

Moreover, it is to be understood that the trench 200 may possess any shape that extends into the substrate 102 and not just the elongated rectilinear shape shown in the figures.

Referring now to FIG. 3, therein is shown the structure of FIG. 2 after further processing.

In at least one embodiment, a second gate dielectric layer, such as a control gate bottom dielectric layer 300 can be formed over, on, or within the trench 200 (e.g., on the mesa sidewall 206, the trench sidewall 202 and the trench bottom 204). It will be appreciated by those skilled in the art that the composition of the cap layer 110 can affect the formation of the control gate bottom dielectric layer 300 over or on the cap layer 110.

The control gate bottom dielectric layer 300 can be made from materials including, but not limited to, silicon oxide, silicon nitride, silicon oxynitride, a high-k dielectric material (i.e., one having a dielectric constant value greater than silicon oxide), or a combination thereof. However, it is to be understood that the type of material chosen for the control gate bottom dielectric layer 300 is not limited to the preceding examples; for example, the control gate bottom dielectric layer 300 may include any material that permits induction and storage of a charge when an appropriate voltage is applied to an appropriate gate. In accordance with the scope of the present embodiments, other materials, which may be known to those skilled in the art for gate structures, may also be used for the control gate bottom dielectric layer 300.

Generally, the control gate bottom dielectric layer 300 can have a thickness in a range of approximately 1 nm to approximately 10 nm, although it is to be understood that larger or smaller thickness may be used as well. Moreover, it will be appreciated by those skilled in the art that the thickness and the material selection of the control gate bottom dielectric layer 300 can be varied to substantially determine its electrical properties, e.g., desired write, erase, and programming speed characteristics.

By way of example, the control gate bottom dielectric layer 300 may be thermally grown using an oxidizing or nitridizing ambient, or deposited using a conventional chemical vapor deposition technique, physical vapor deposition technique, atomic layer deposition technique, or a combination thereof.

Formed over or on the control gate bottom dielectric layer 300 can be a charge storage material 302. A layer of the charge storage material 302 can be formed on all exposed surfaces of the integrated circuit system 100. It will be appreciated by those skilled in the art that the charge storage material 302 can be non-selectively deposited over or on all exposed surfaces whether vertical or horizontal and independent of surface orientation, thereby forming a substantially uniform layer.

Generally, the charge storage material 302 can be formed of a material capable of storing a charge, such as silicon, silicon germanium, a nitride, or metal-containing material; although, it is to be understood that other charge storage materials may be used. In at least one embodiment, the charge storage material 302 can include discontinuous silicon nanocrystals or metal nanoclusters. It is to be understood that the terms nanocrystals and nanoclusters as used herein includes charge storage materials that are not necessarily crystalline in structure.

Generally, the charge storage material 302 may include nanocrystals and nanoclusters that range in diameter between about 10 angstroms to about 150 angstroms, although it is understood that larger or smaller diameters can be used. However, it is to be understood that the nanocrystals and nanoclusters of the charge storage material 302 are not to be formed so large as to form a continuous structure (i.e., the nanocrystals and nanoclusters are to be formed as discrete discontinuous elements). Additionally, it is to be understood that the shapes of the nanocrystals or nanoclusters within the charge storage material 302 need not necessarily be spherical and may include other non-spherical shapes as well. Moreover, it will be appreciated by those skilled in the art that the size and density of the charge storage material 302 can be strategically optimized to obtain desired write, erase, and programming speed characteristics

The methods and techniques used to form the charge storage material 302 are well known within the art and not repeated herein.

Subsequent to forming the charge storage material 302 a second gate dielectric layer, such as a control gate top dielectric layer 304 can be non-selectively formed over or on the integrated circuit system 100 (e.g., conformally deposited within the trench 200 and over the mesa 104). Generally, the control gate top dielectric layer 304 overlies and encapsulates the charge storage material 302 and the control gate bottom dielectric layer 300. The control gate top dielectric layer 304 may include any one or more materials or be formed using any of the embodiments as described with respect to the control gate bottom dielectric layer 300. The control gate top dielectric layer 304 can have the same or different composition compared to the control gate bottom dielectric layer 300 and may be formed using the same or different formation technique compared to the control gate bottom dielectric layer 300.

It will be appreciated by those skilled in the art that the thickness and the material selection of the control gate top dielectric layer 304 can be varied to substantially determine its electrical properties, e.g., its desired write, erase, and programming speed characteristics.

By way of example, the control gate top dielectric layer 304 may be deposited using a conventional chemical vapor deposition technique, physical vapor deposition technique, atomic layer deposition technique, or a combination thereof.

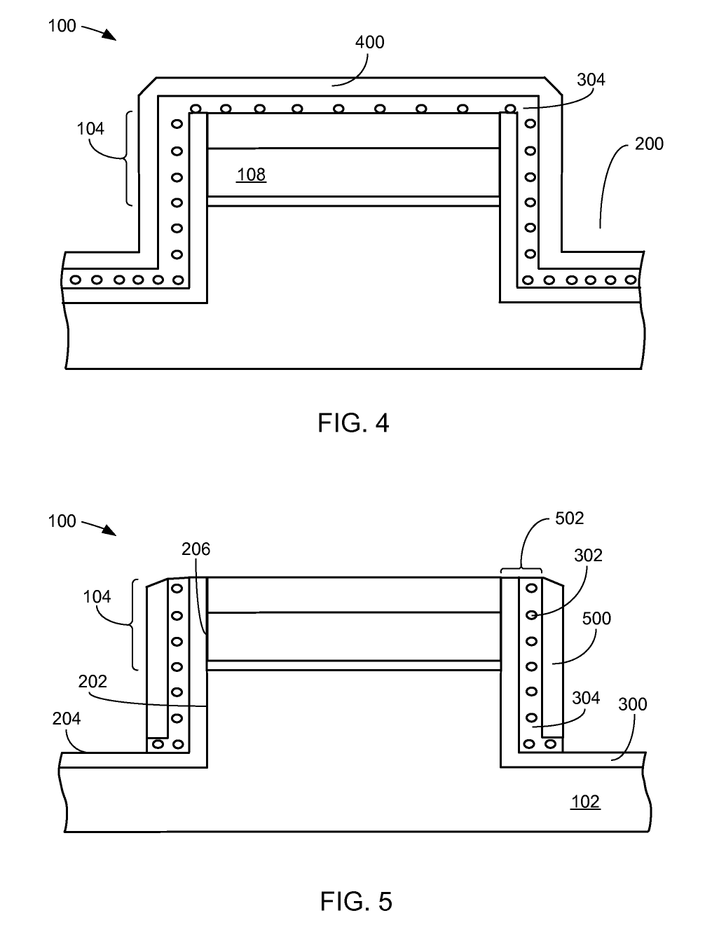

Referring now to FIG. 4, therein is shown the structure of FIG. 3 after depositing a control gate layer 400. The control gate layer 400, such as a second gate layer, can be non-selectively formed over or on the integrated circuit system 100, or more specifically over the control gate top dielectric layer 304 (e.g., conformally deposited within the trench 200 and over the mesa 104).

The control gate layer 400 may include any one or more materials or be formed using any of the embodiments as described with respect to the select gate layer 108. The control gate layer 400 can have the same or different composition compared to the select gate layer 108 and may be formed using the same or different formation technique compared to the select gate layer 108.

Generally, the thickness of the control gate layer 400 can vary with the design specifications and/or the current technology process node (e.g., 45 nm, 32 nm, etc.) for the integrated circuit system 100. However, it will be appreciated by those skilled in the art that the thickness of the control gate layer 400 can be modified and/or optimized by the device designer to reduce the area consumed by the individual unit cells of a nonvolatile memory structure. Moreover, it will be appreciated by those skilled in the art that the thickness of the control gate layer 400 can depend upon the desired write, erase, and programming speed characteristics of the integrated circuit system 100.

Referring now to FIG. 5, therein is shown the structure of FIG. 4 after further processing. Generally, at this stage of manufacture the integrated circuit system 100 is subject to an etching process that removes portions of the control gate layer 400 (of FIG. 4), the control gate top dielectric layer 304 (of FIG. 4), and the charge storage material 302 (of FIG. 4) from over horizontal surfaces of the integrated circuit system 100 to form a second gate, such as a control gate 500, and a second gate dielectric, such as a control gate dielectric 502. It is to be understood that the control gate dielectric 502 includes the control gate bottom dielectric layer 300, the charge storage material 302, and the control gate top dielectric layer 304, formed between the control gate 500 and the mesa 104 and the substrate 102.

In at least one embodiment, the control gate 500 and the control gate dielectric 502 can be formed along the entire length or height of the mesa sidewall 206, the trench sidewall 202 and over a portion of the trench bottom 204. Generally, the control gate 500 can be described as vertically oriented, meaning that the major axis of the control gate 500 lies in a plane that is perpendicular to the conventional surface of the substrate 102. In such cases, the width of the control gate 500 and the control gate dielectric 502 formed along each of the trench sidewall 202 can cover between about 5 percent to about 45 percent of the trench bottom 204, thereby leaving a substantially centrally located portion of the trench bottom 204 exposed for further processing. However, it is to be understood that other heights and widths of the control gate 500 and the control gate dielectric 502 can be used to satisfy design requirements of the integrated circuit system 100 (e.g., desired write, erase, and programming speed characteristics).

As an exemplary illustration, portions of the control gate layer 400, the control gate top dielectric layer 304, and the charge storage material 302 can be patterned and/or removed by an anisotropic etching process, such as a reactive ion etch (RIE). It will be appreciated by those skilled in the art that the etching process used to form the control gate 500 and the control gate dielectric 502 can be described as a self-aligned process. Although it is to be understood that other etch processes can be used as well.

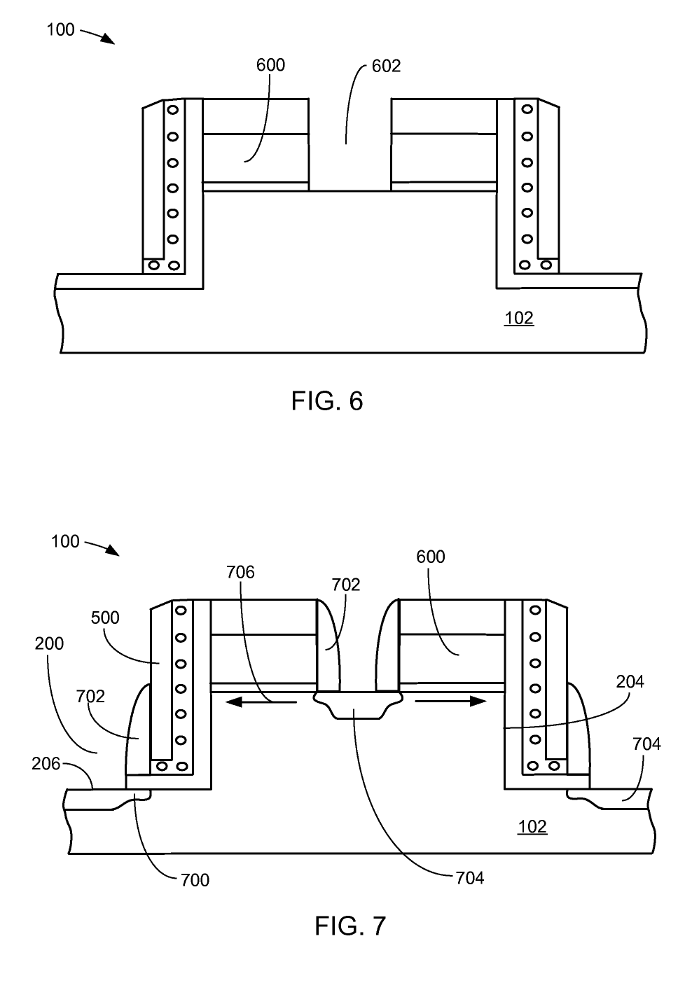

Referring now to FIG. 6, therein is shown the structure of FIG. 5 after forming a first gate. Generally, the first gate, such as a select gate 600, can be formed by etching existing layers (e.g., the layers of the mesa 104) already formed over the integrated circuit system 100. Accordingly, it is to be understood that the select gate 600 can be formed without requiring the additional processing step of depositing the necessary material to form the select gate 600. In such cases, the select gate 600 can be formed above or on the substrate 102 with a horizontal orientation that lies in a plane that is parallel with the conventional surface of the substrate 102.

In at least one embodiment, each of the select gate 600 can be formed by etching/removing a portion of the cap layer 110 (of FIG. 1), the select gate layer 108 (of FIG. 1), and the select gate dielectric layer 106 (of FIG. 1) to form an opening 602. It will be appreciated by those skilled in the art that the dimensions of the opening 602 can be limited by the need to form doped regions between each of the select gate 600.

The materials and techniques used to etch the cap layer 110, the select gate layer 108, and the select gate dielectric layer 106 are well known within the art and not repeated herein.

Referring now to FIG. 7, therein is shown the structure of FIG. 6 after further processing.

Generally, the integrated circuit system 100 may include a doped extension region 700 formed adjacent each of the control gate 500 and the select gate 600. It will be appreciated by those skilled in the art that the doped extension region 700 can be formed by a shallow implant often termed a lightly doped drain process, thereby improving short channel effects by decreasing the electric field between a junction region and a channel region. The impurities used to form the doped extension region 700 may include n-type or p-type, depending on the type of device being formed (e.g., n-type impurities for an NFET device and p-type impurities for a PFET device).

The integrated circuit system 100 may also include a gate spacer 702 formed adjacent each of the control gate 500 and the select gate 600. Generally, the gate spacer 702 may include dielectric materials such as an oxide, a nitride, or a combination thereof In other embodiments, the gate spacer 702 may also include any type of stress-inducing material that transfers its inherent or intrinsic stress to the control gate 500 and/or the select gate 600. The gate spacer 702 can be formed by a variety of techniques, including, but not limited to, a nonselective deposition by physical vapor deposition, chemical vapor deposition and/or thermal oxidation, followed by an appropriate anisotropic etch.

However, it is to be understood that the type of materials and deposition technique chosen for the gate spacer 702 are not limited to the above examples and may include any material or deposition technique that permits electrical isolation of the control gate 500 and the select gate 600 and/or formation of a lateral dopant profile adjacent each of the control gate 500 and the select gate 600.

Moreover, it is to be understood that the thickness and/or width of each of the gate spacer 702 may determine, at least in part, the location of a subsequently formed source and drain region, the location of a low resistance electrical contact, and/or the proximity of a subsequently deposited stressor layer. Accordingly, the thickness and/or width of each of the gate spacer 702 can be modulated to meet the particular design specifications desired for the integrated circuit system 100.

Generally, the gate spacer 702 may include a thickness ranging from about 10 angstroms to about 200 angstroms. However, it is to be understood that the thickness of the gate spacer 702 may be larger or smaller and may vary with the design specifications of the device.

A doped region 704 may also be formed adjacent each of the control gate 500 and the select gate 600. It will be appreciated by those skilled in the art that the doped region 704 can be formed by a medium to high dose implant. The impurities used to form the doped region 704 may include n-type or p-type, depending on the type of device being formed (e.g., n-type impurities for an NFET device and p-type impurities for a PFET device). Typically, the impurities used to form the doped region 704 are of the same conductivity type as the impurities used to form the doped extension region 700.

It has been discovered that having each of the doped region 704 separated vertically as well as horizontally allows easier optimization of reliability parameters without affecting cell size of a nonvolatile memory structure. Moreover, it has been discovered that the vertical orientation of the control gate 500 along the trench sidewall 202 permits a reduction in area consumed by the control gate 500 compared to that of a conventional control gate structure, while allowing the programming current, as represented by arrow 706, to flow from the doped region 704 adjacent the select gate 600 directly towards the control gate 500, thereby improving the programming speed characteristics of the integrated circuit system 100. Furthermore, it has been discovered that the total gate length of the control gate 500 can vary with the depth of the trench 200 and can be defined as the distance between the select gate 600 and the doped region 704 adjacent the control gate 500 within the substrate 102.

It is to be understood that during operation, the control gate 500 can be configured to create and control a channel in the substrate 102 adjacent to the trench sidewall 202 and the trench bottom 204, while the select gate 600 can be configured to create and control a channel in the substrate 102 adjacent the select gate 600.

Moreover, it will be appreciated by those skilled in the art that additional dielectrics, electrical contacts, conductive plugs, and/or local/global interconnects can be formed over the control gate 500, the select gate 600, and the doped region 704 as is well known in the art.

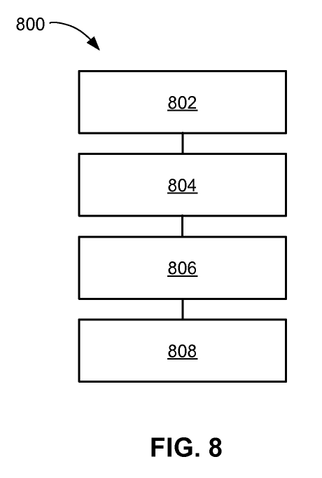

Referring now to FIG. 8, therein is shown a flow chart of a method 800 of manufacture of the integrated circuit system 100 in an embodiment of the present invention. The method 800 includes: providing a mesa over a substrate in a block 802; forming a trench in the substrate adjacent the mesa in a block 804; forming a second gate and a charge storage material along a trench sidewall in a block 806; and forming a first gate from the mesa in a block 808.

The resulting method, process, apparatus, device, product, and/or system is straightforward, cost-effective, uncomplicated, highly versatile, accurate, sensitive, and effective, and can be implemented by adapting known components for ready, efficient, and economical manufacturing, application, and utilization.

It has been discovered that the present invention thus has numerous aspects. One such aspect is that the present invention helps to reduce memory cell area by forming a vertical control gate along a trench sidewall, thereby permitting a reduction in area consumed by the vertical control gate compared to that of a conventional control gate structure. It will be appreciated by those skilled in the art that the memory capacity per fixed die area can be increased by utilizing the vertical control gate with a reduced area requirement disclosed herein.

It has been discovered that the present invention helps to provide improved methods of faster programming by directing the programming current directly towards the control gate, e.g., the programming current flow can be directed perpendicular to the major surface/plane of the control gate. It will be appreciated by those skilled in the art that such a programming current flow orientation can help to improve the charge trapping efficiency of the integrated circuit system.

It has been discovered that the present invention provides a method wherein the control gate patterning utilizes a self-aligned process, thereby eliminating the need for an additional/extra masking step.

It has been discovered that the present invention employs both planar and sidewall gate structures, thereby allowing a device designer to separately optimize the two different gate structures.

It has been discovered that the present invention provides a self-aligned process by defining the planar select gate first, i.e., before forming the control gate.

It has been discovered that the present invention provides a reduced number of manufacturing steps.

Yet another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit system comprising:
providing a mesa over a substrate;
forming a trench in the substrate adjacent the mesa;
forming a second gate and a charge storage material along a trench sidewall; and
forming a first gate from the mesa.

2. The method as claimed in claim 1 wherein:
providing the mesa includes providing a select gate dielectric layer, a select gate layer and a cap layer.

3. The method as claimed in claim 1 wherein:
forming the trench in the substrate includes a self aligned process.

4. The method as claimed in claim 1 wherein:
forming the charge storage material includes forming silicon nanocrystals or metal nanoclusters.

5. The method as claimed in claim 1 wherein:
forming the first gate from the mesa includes etching a group of layers deposited before forming the trench.

6. A method of manufacture of an integrated circuit system comprising:
providing a first gate layer formed over a substrate;
forming a trench in the substrate aligned to the first gate layer;
forming a charge storage material within the trench and over the first gate layer;
forming a second gate layer over the charge storage material within the trench and over the first gate layer;
forming a second gate and a second gate dielectric along a trench sidewall from the second gate layer and the charge storage material; and
forming a first gate from the first gate layer.

7. The method as claimed in claim 6 wherein:
forming the first gate includes forming a select gate.

8. The method as claimed in claim 6 wherein:
forming the second gate includes forming a control gate.

9. The method as claimed in claim 6 wherein:
forming the second gate dielectric includes forming a control gate bottom dielectric layer, a charge storage material, and a control gate top dielectric layer;

10. The method as claimed in claim 6 wherein:
forming the trench affects the desired gate length of a control gate.

11. A method of manufacture of an integrated circuit system comprising:
providing a mesa including a first gate dielectric, a first gate layer, and a cap layer over a substrate;
forming a trench in the substrate aligned to the mesa;
forming a charge storage material within the trench and over the mesa;
forming a second gate layer over the charge storage material within the trench and over the mesa;
forming a second gate and a second gate dielectric along a trench sidewall from the second gate layer and the charge storage material;
forming a first gate from the mesa; and
forming a doped region adjacent the first gate and the second gate.

12. The system as claimed in claim 11 wherein:
forming the first gate includes forming a select gate.

13. The system as claimed in claim 11 wherein:
forming the second gate includes forming a control gate.

14. The system as claimed in claim 11 wherein:
forming the charge storage material includes forming silicon nanocrystals or metal nanoclusters.

15. The system as claimed in claim 11 wherein:
forming the first gate from the mesa includes etching a group of layers deposited before forming the trench.

16. The system as claimed in claim 11 wherein:
forming the second gate dielectric includes forming a control gate bottom dielectric layer, a charge storage material, and a control gate top dielectric layer.

17. The system as claimed in claim 16 wherein:
forming the trench affects the desired gate length of a control gate

18. The system as claimed in claim 16 wherein:
forming the second gate includes forming a control gate along a mesa sidewall, the trench sidewall and a portion of a trench bottom.

19. The system as claimed in claim 16 wherein:
forming the second gate includes a self-aligned process.

20. The system as claimed in claim 16 further comprising:
configuring the integrated circuit system to include a nonvolatile memory.
